(19) United States
(12) Patent Application Publication
(10) Pub. No.: US 2022/0154365 A1
(43) Pub. Date: May 19, 2022

(54) NON-CONTACT SYSTEMS AND METHODS FOR DETERMINING DISTANCE BETWEEN SILICON MELT AND REFLECTOR IN A CRYSTAL PULLER

(71) Applicant: GlobalWafers Co., Ltd., Hsinchu (TW)

(72) Inventors: Benjamin Michael Meyer, Defiance, MO (US); William Lynn Luter, St. Charles, MO (US); JaeWoo Ryu, Chesterfield, MO (US)

(21) Appl. No.: 17/455,347

(22) Filed: Nov. 17, 2021

Related U.S. Application Data
(60) Provisional application No. 63/198,870, filed on Nov. 19, 2020.

(51) Int. Cl. C30B 15/20; C30B 29/06; G01S 17/48; G06T 7/00; G06T 7/70

(52) U.S. Cl. CPC C30B 15/20; C30B 29/06; G01S 17/48; G06T 2207/10028; G06T 7/70; G06T 2207/30148; G06T 7/0004

(57) ABSTRACT

A measurement system includes a reflector defining a central passage and an opening, a measurement assembly, and a controller. The measurement assembly includes a run pin having a head that is visible through the opening, a camera to capture images through the opening in the reflector, and a laser to transmit coherent light through the opening to the head of the run pin to produce a reflection of the run pin on the surface of the silicon melt. The controller is programmed to control the laser to direct coherent light from the laser to the run pin, control the camera capture images through the opening while the coherent light is directed at the run pin, and determine a distance between the surface of the silicon melt and a bottom surface of the reflector based on a location of the reflection of the run pin in the captured images.

### CROSS-REFERENCE TO RELATED APPLICATIONS

This application claims priority to U.S. Provisional Patent Application Ser. No. 63/198,870, filed Nov. 19, 2020, the entire disclosure of which is hereby incorporated by reference in its entirety.

### FIELD

This disclosure generally relates to the production of silicon ingots, and more specifically, to non-contact methods and systems for determination of the distance between a silicon melt and a reflector in a crystal puller.

### BACKGROUND

Some crystal pullers include a reflector positioned above a silicon melt. During operation of the crystal puller, it is beneficial to know the distance (referred to as “HR”) between the bottom of the reflector and the surface of the silicon melt.

HR measurement requirements can be less than 1 mm with accuracies desired in the 0.1 to 0.2 mm range. The measurement is difficult to make with known methods because measuring HR involves observing and tracking features inside an extremely hot puller under vacuum or low pressure conditions. These conditions generally limit the sensors and materials that can be used inside the puller to make measurements. Because thermal expansion will generally move parts that are not actively cooled, measurements made before a pull or run starts may not be usable or helpful after the puller is brought up to run temperature. Thus, known methods (such as camera images) that rely on measured or known cold distances will have errors.

Some known methods use a camera to determine HR. Such methods typically rely on values input from the theoretical geometry. Differences between the actual geometry and the theoretical geometry can introduce errors. These methods may include a calibration for the camera on a separate jig that is built to the theoretical distances and angles that the puller should have. Again, differences between the actual geometry and the theoretical geometry on the calibration jig itself can introduce additional errors. Further, such methods often rely on features of the geometry of graphite components in reflections of the melt in the camera images to determine HR. Since the brightness intensity of these images can vary greatly over the run it can be difficult to obtain a consistent signal causing a variation in HR during the run.

Known methods may also have software driven problems. For example, HR measurements are sometimes based partially on variation in the diameter of the crystal, with HR varying by as much as 0.5 mm. This variation in measured HR arises because of how the center of the crystal is found and its relationship to the center of the reflector, which is used to establish the position of the reflector. Also, changes in radial location of the reflector can be translated to vertical changes, which directly impacts HR. Finally, the camera measurement typically relies on detecting the leading edge of the hot crucible wall reflected onto the meniscus. This edge location is used in the melt level measurement to determine height. Therefore height is dependent on both the shape of the meniscus, which changes as a function of crystal growth pull speed, and the surface curvature of the melt surface which is a function of the crucible rotation. The variation due to the leading edge is difficult to calculate. The variation of the melt curvature can be easily calculated, and can vary by as much as 7 mm overall height difference.

Another method used to determine HR is a dipstick method. In this method, a quartz pin that extends a known distance from the bottom of the reflector is dipped into the melt. Because the distance between the bottom of the pin and the bottom of the reflector is measured before the reflector is installed in the puller, when the pin touches the melt, the HR at that time is known. This only provides an initial measurement and another method must be used (such as camera tracking) to determine HR at different melt elevations. In practice this method is difficult to implement because touching the quartz pin to the melt can causing wicking of the silicon along the outside of the pin due to melted silicon's surface tension. This can make it difficult to determine with accuracy when the pin touched the melt surface (rather than just coming close enough to it to allow the silicon to contact the pin). There are also problems in maintaining the length of the pin over the course of the run due to its direct contact with the melt, which is a problem if a recalibration is desired during the run because the distance between the bottom of the pin and the bottom of the reflector would now become unknown.

This background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF SUMMARY

One aspect of the present disclosure is a real-time measurement system in a crystal puller for determining a distance between a silicon melt in a crucible and a reflector while a crystal is being pulled from the silicon melt. The system includes a reflector defining a central passage through which the crystal is pulled and an opening, a measurement assembly, and a controller. The measurement assembly includes a run pin having a head that is visible through the opening, a camera to capture images through the opening in the reflector, a laser to selectively transmit coherent light through the opening to the head of the run pin to produce a reflection of the run pin on a surface of the silicon melt. Each image captured by the camera includes the surface of the silicon melt in the crystal puller. The controller is connected to the camera and the laser. The controller is programmed to control the laser to direct coherent light from the laser to the run pin, control the camera capture images through the opening in the reflector assembly while the coherent light is directed at the run pin, the captured images including at least a part of the surface of the silicon melt on which the reflection of the run pin is visible, and determine a distance between the surface of the silicon melt and a bottom surface of the reflector based on a location of the reflection of the run pin in the captured images.

Another aspect of this disclosure is a method of determining a distance between a silicon melt in a crucible and a reflector in a crystal puller while a crystal is being pulled from the silicon melt using a measurement system including a camera, a laser, a run pin, and a controller. The method includes directing coherent light from the laser to the run pin mounted on the reflector and visible through an opening in the reflector, capturing images through the opening in the reflector using the camera while the coherent light is directed at the run pin, the captured images including at least a part of a surface of the silicon melt on which the reflection of the run pin is visible, and determining, by the controller, a distance between the surface of the silicon melt and a bottom surface of the reflector based on a location of the reflection of the run pin in the captured images.

Various refinements exist of the features noted in relation to the above-mentioned aspect. Further features may also be incorporated in the above-mentioned aspect as well. These refinements and additional features may exist individually or in any combination. For instance, various features discussed below in relation to any of the illustrated embodiments may be incorporated into the above-described aspect, alone or in any combination.

### BRIEF DESCRIPTION OF THE DRAWINGS

FIG. 1 is a cross-section view of an ingot puller apparatus used to pull a single crystal silicon ingot from a silicon melt.

FIG. 2 is a cross-section of an ingot puller apparatus.

FIG. 3 is a partial front view of a single crystal silicon ingot grown by the Czochralski method.

FIG. 4 is a block diagram of a computing device for use in the control system of the ingot puller apparatus of FIG. 1.

FIG. 5 is a diagram of a measurement assembly for use in the ingot puller apparatus of FIG. 1.

FIG. 6 is a view of a camera assembly of the measurement assembly of FIG. 5.

FIG. 7 is a view of a laser assembly of the measurement assembly of FIG. 5.

FIG. 8 is a cross-sectional view of the laser assembly taken along the line A-A in FIG. 7.

FIG. 9 is a view of the reflector for use with the measurement system of FIG. 5.

FIG. 10 is a view directly down the cutout in the reflector assembly of FIG. 9.

FIG. 11 is a close up view of a run pin and an anchor pin of the measurement system mounted in the reflector of FIG. 9.

FIG. 12 is a view of the anchor pin of FIG. 11 extending past the bottom of the reflector.

FIG. 13 is a side view of the anchor pin of FIG. 11.

FIG. 14 is an example of a view the camera in FIG. 6 during anchoring.

FIG. 15 is an example of a view the camera in FIG. 6 during anchoring after lowering the melt from the view in FIG. 14.

FIG. 16 is a diagram of the geometry and values used to anchor the HR value using the measurement system of FIG. 5.

FIG. 17 is an example of a view the camera in FIG. 6 when calibrating the camera after anchoring.

FIG. 18 is an example of a view the camera in FIG. 6 when calibrating the camera after lowering the melt from the view in FIG. 17.

FIG. 19 is an example of a view the camera in FIG. 6 when calibrating the camera after lowering the melt from the view in FIG. 18.

FIG. 20 is a view of another example pin for use as an anchor pin or a run pin in the measurement system.

FIG. 21 is a view of another example pin for use as an anchor pin or a run pin in the measurement system.

FIG. 22 is a view from within the opening in the reflector of a pin in an embodiment using a single pin with a single spherical head.

FIG. 23 is a view of the pin in FIG. 22 viewed down the opening in the reflector.

FIG. 24 is a view from within the opening in the reflector of a pin in an embodiment using a single pin with a single spherical head extending out from a wall of the reflector opening.

FIG. 25 is a view of the pin in FIG. 22 viewed down the opening in the reflector.

FIG. 26 an example image of an illuminated pin and a reflection of the pin captured by the camera during at a start of a run.

FIG. 27 is an example image of the illuminated pin and the reflection of the pin captured by the camera during the run.

Like reference symbols in the various drawings indicate like elements.

### DETAILED DESCRIPTION

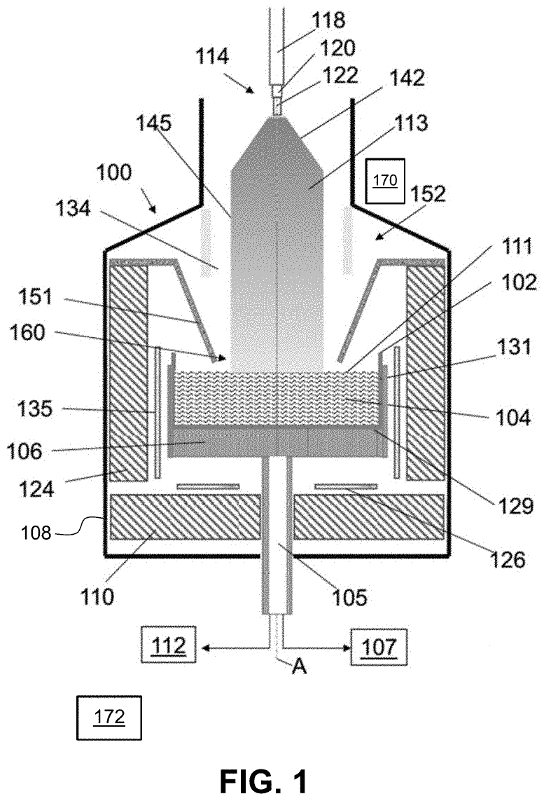

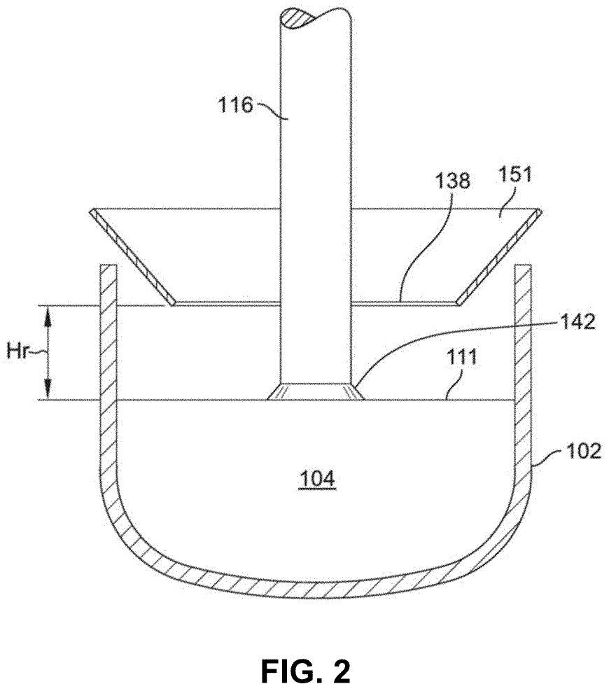

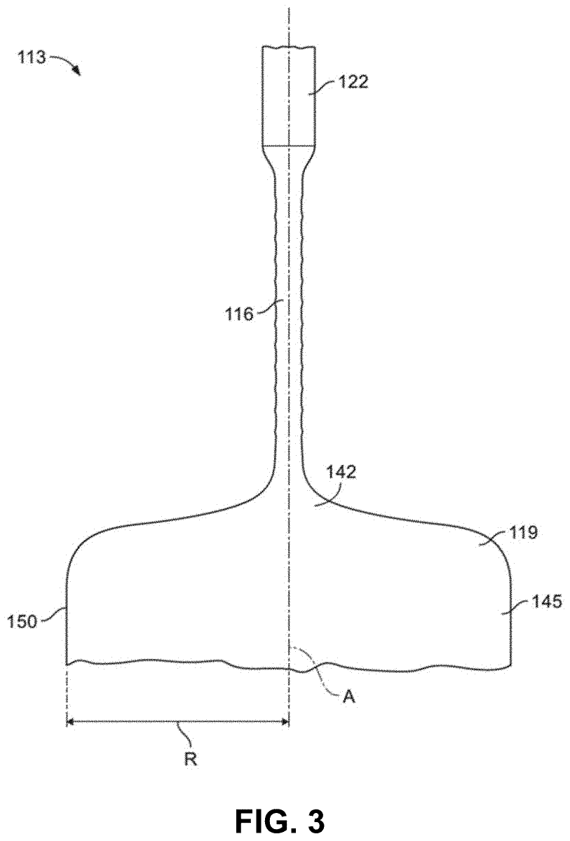

An ingot puller apparatus (or more simply “ingot puller” or a “crystal puller”) for growing a monocrystalline silicon ingot will be described with reference to FIGS. 1-3. FIG. 1 is a cross-section view of an ingot puller apparatus indicated generally at “100” used to pull a single crystal silicon ingot from a silicon melt. FIG. 2 is a cross-section of the ingot puller apparatus 100, and FIG. 3 is a partial front view of a single crystal silicon ingot grown by the Czochralski method, for example in the ingot puller apparatus 100.

The ingot puller apparatus 100 includes a crystal puller housing 108 that defines a growth chamber 152 for pulling a silicon ingot 113 from a melt 104 of silicon. A control system 172 (also referred to as a “controller”) controls operation of the ingot puller 100 and its components. The ingot puller apparatus 100 includes a crucible 102 disposed within the growth chamber 152 for holding the melt 104 of silicon. The crucible 102 is supported by a susceptor 106.

The crucible 102 includes a floor 129 and a sidewall 131 that extends upward from the floor 129. The sidewall 131 is generally vertical. The floor 129 includes the curved portion of the crucible 102 that extends below the sidewall 131. Within the crucible 102 is a silicon melt 104 having a melt surface 111 (i.e., melt-ingot interface). The susceptor 106 is supported by a shaft 105. The susceptor 106, crucible 102, shaft 105 and ingot 113 have a common longitudinal axis A or “pull axis” A.

A pulling mechanism 114 is disposed within the ingot puller apparatus 100 for growing and pulling an ingot 113 from the melt 104. Pulling mechanism 114 includes a pulling cable 118, a seed holder or chuck 120 coupled to one end of the pulling cable 118, and a seed crystal 122 coupled to the seed holder or chuck 120 for initiating crystal growth. One end of the pulling cable 118 is connected to a pulley (not shown) or a drum (not shown), or any other suitable type of lifting mechanism, for example, a shaft, and the other end is connected to the chuck 120 that holds the seed crystal 122. In operation, the seed crystal 122 is lowered to contact the melt 104. The pulling mechanism 114 is operated to cause the seed crystal 122 to rise. This causes a single crystal ingot 113 to be pulled from the melt 104.

During heating and crystal pulling, a crucible drive unit 107 (e.g., a motor) rotates the crucible 102 and susceptor 106. A lift mechanism 112 raises and lowers the crucible 102 along the pull axis A during the growth process. As the ingot grows, the silicon melt 104 is consumed and the height of the melt in the crucible 102 decreases. The crucible 102 and susceptor 106 may be raised to maintain the melt surface 111 at or near the same position relative to the ingot puller apparatus 100.

A crystal drive unit (not shown) may also rotate the pulling cable 118 and ingot 113 in a direction opposite the direction in which the crucible drive unit 107 rotates the crucible 102 (e.g., counter-rotation). In embodiments using iso-rotation, the crystal drive unit may rotate the pulling cable 118 in the same direction in which the crucible drive unit 107 rotates the crucible 102. In addition, the crystal drive unit raises and lowers the ingot 113 relative to the melt surface 111 as desired during the growth process.

The ingot puller apparatus 100 may include an inert gas system to introduce and withdraw an inert gas such as argon from the growth chamber 152. The ingot puller apparatus 100 may also include a dopant feed system (not shown) for introducing dopant into the melt 104.

According to the Czochralski single crystal growth process, a quantity of polycrystalline silicon, or polysilicon, is charged to the crucible 102 (e.g., charge of 250 kg or more). A variety of sources of polycrystalline silicon may be used including, for example, granular polycrystalline silicon produced by thermal decomposition of silane or a halosilane in a fluidized bed reactor or polycrystalline silicon produced in a Siemens reactor. Once polycrystalline silicon is added to the crucible to form a charge, the charge is heated to a temperature above about the melting temperature of silicon (e.g., about 1412° C.) to melt the charge. In some embodiments, the charge (i.e., the resulting melt) is heated to a temperature of at least about 1425° C., at least about 1450° C. or even at least about 1500° C. The ingot puller apparatus 100 includes bottom insulation 110 and side insulation 124 to retain heat in the puller apparatus 100. In the illustrated embodiment, the ingot puller apparatus 100 includes a bottom heater 126 disposed below the crucible floor 129. The crucible 102 may be moved to be in relatively close proximity to the bottom heater 126 to melt the polycrystalline charged to the crucible 102.

To form the ingot, the seed crystal 122 is contacted with the surface 111 of the melt 104. The pulling mechanism 114 is operated to pull the seed crystal 122 from the melt 104. The ingot 113 includes a crown portion 142 in which the ingot transitions and tapers outward from the seed crystal 122 to reach a target diameter. The ingot 113 includes a constant diameter portion 145 or cylindrical “main body” of the crystal which is grown by increasing the pull rate. The main body 145 of the ingot 113 has a relatively constant diameter. The ingot 113 includes a tail or end-cone (not shown) in which the ingot tapers in diameter after the main body 145. When the diameter becomes small enough, the ingot 113 is then separated from the melt 104. The ingot 113 has a central longitudinal axis A that extends through the crown portion 142 and a terminal end of the ingot 113.

The ingot puller apparatus 100 includes a side heater 135 and a susceptor 106 that encircles the crucible 102 to maintain the temperature of the melt 104 during crystal growth. The side heater 135 is disposed radially outward to the crucible sidewall 131 as the crucible 102 travels up and down the pull axis A. The side heater 135 and bottom heater 126 may be any type of heater that allows the side heater 135 and bottom heater 126 to operate as described herein. In some embodiments, the heaters 135, 126 are resistance heaters. The side heater 135 and bottom heater 126 may be controlled by a control system 172 so that the temperature of the melt 104 is controlled throughout the pulling process.

The ingot puller apparatus 100 also includes a reflector 151 (or “heat shield”) disposed within the growth chamber 152 and above the melt 104 which shrouds the ingot 113 during ingot growth. The reflector 151 may be partially disposed within the crucible 102 during crystal growth. The heat shield 151 defines a central passage 160 for receiving the ingot 113 as the ingot is pulled by the pulling mechanism 114.

The reflector 151 is, in general, a heat shield adapted to retain heat underneath itself and above the melt 104. In this regard, any reflector design and material of construction (e.g., graphite or gray quartz) known in the art may be used without limitation. The reflector 151 has a bottom 138 (FIG. 2) and the bottom 138 of the reflector 151 is separated from the surface of the melt by a distance HR during ingot growth.

The ingot puller apparatus includes a measurement assembly 170 that is used as part of a measurement system to determine the distance between the bottom 138 of the reflector 151 and the surface of the melt (i.e., to determine HR) during ingot growth.

A single crystal silicon ingot 113 produced in accordance with embodiments of the present disclosure and, generally, the Czochralski method is shown in FIG. 3. The ingot 113 includes a neck 116, an outwardly flaring portion 142 (synonymously “crown” or “cone”), a shoulder 119 and a constant diameter main body 145. The neck 116 is attached to the seed crystal 122 that was contacted with the melt and withdrawn to form the ingot 113. The main body 145 is suspended from the neck 116. The neck 116 terminates once the cone portion 142 of the ingot 113 begins to form.

The constant diameter portion 145 of the ingot 113 has a circumferential edge 150, a central axis A that is parallel to the circumferential edge 150 and a radius R that extends from the central axis A to the circumferential edge 145. The central axis A also passes through the cone 142 and neck 116. The diameter of the main ingot body 145 may vary and, in some embodiments, the diameter may be about 150 mm, about 200 mm, about 300 mm, greater than about 300 mm, about 450 mm or even greater than about 450 mm.

The single crystal silicon ingot 113 may generally have any resistivity. The single crystal silicon ingot 113 may be doped or undoped.

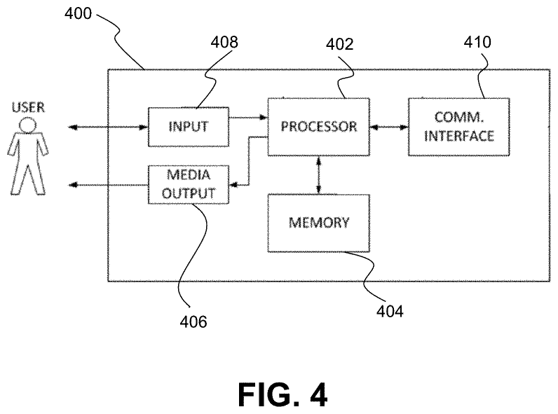

FIG. 4 is an example computing device 400 that may be used as or as part of the control system 172. The computing device 400 includes a processor 402, a memory 404, a media output component 406, an input device 408, and a communications interface 410. Other embodiments include different components, additional components, and/or do not include all components shown in FIG. 4.

The processor 402 is configured for executing instructions. In some embodiments, executable instructions are stored in the memory 404. The processor 402 may include one or more processing units (e.g., in a multi-core configuration). The term processor, as used herein, refers to central processing units, microprocessors, microcontrollers, reduced instruction set circuits (RISC), application specific integrated circuits (ASIC), a programmable logic circuit (PLC), and any other circuit or processor capable of executing the functions described herein. The above are examples only, and are thus not intended to limit in any way the definition and/or meaning of the term “processor.”

The memory 404 stores non-transitory, computer-readable instructions for performance of the techniques described herein. Such instructions, when executed by the processor 402, cause the processor 402 to perform at least a portion of the methods described herein. In some embodiments, the memory 404 stores computer-readable instructions for providing a user interface to the user via media output component 406 and, receiving and processing input from input device 408. The memory 404 may include, but is not limited to, random access memory (RAM) such as dynamic RAM (DRAM) or static RAM (SRAM), read-only memory (ROM), erasable programmable read-only memory (EPROM), electrically erasable programmable read-only memory (EEPROM), and non-volatile RAM (NVRAM). Although illustrated as separate from the processor 402, in some embodiments the memory 404 is combined with the processor 402, such as in a microcontroller or microprocessor, but may still be referred to separately. The above memory types are examples only, and are thus not limiting as to the types of memory usable for storage of a computer program.

The media output component 406 is configured for presenting information to the user (e.g., the operator of the system). The media output component 406 is any component capable of conveying information to the user. In some embodiments, the media output component 406 includes an output adapter such as a video adapter and/or an audio adapter. The output adapter is operatively connected to the processor 402 and operatively connectable to an output device such as a display device (e.g., a liquid crystal display (LCD), light emitting diode (LED) display, organic light emitting diode (OLED) display, cathode ray tube (CRT), “electronic ink” display, one or more light emitting diodes (LEDs)) or an audio output device (e.g., a speaker or headphones).

The computing device 400 includes, or is connected to, the input device 408 for receiving input from the user. The input device 408 is any device that permits the computing device 400 to receive analog and/or digital commands, instructions, or other inputs from the user, including visual, audio, touch, button presses, stylus taps, etc. The input device 408 may include, for example, a variable resistor, an input dial, a keyboard/keypad, a pointing device, a mouse, a stylus, a touch sensitive panel (e.g., a touch pad or a touch screen), a gyroscope, an accelerometer, a position detector, an audio input device, or any combination thereof. A single component such as a touch screen may function as both an output device of the media output component 406 and the input device 408.

The communication interface enables the computing device 400 to communicate with remote devices and systems, such as remote sensors, remote databases, remote computing devices, and the like, and may include more than one communication interface for interacting with more than one remote device or system. The communication interfaces may be wired or wireless communications interfaces that permit the computing device 400 to communicate with the remote devices and systems directly or via a network. Wireless communication interfaces may include a radio frequency (RF) transceiver, a Bluetooth® adapter, a Wi-Fi transceiver, a ZigBee® transceiver, a near field communication (NFC) transceiver, an infrared (IR) transceiver, and/or any other device and communication protocol for wireless communication. (Bluetooth is a registered trademark of Bluetooth Special Interest Group of Kirkland, Wash.; ZigBee is a registered trademark of the ZigBee Alliance of San Ramon, Calif.) Wired communication interfaces may use any suitable wired communication protocol for direct communication including, without limitation, USB, RS232, I2C, SPI, analog, and proprietary I/O protocols. In some embodiments, the wired communication interfaces include a wired network adapter allowing the computing device 400 to be coupled to a network, such as the Internet, a local area network (LAN), a wide area network (WAN), a mesh network, and/or any other network to communicate with remote devices and systems via the network.

The computer systems discussed herein may include additional, less, or alternate functionality, including that discussed elsewhere herein. The computer systems discussed herein may include or be implemented via computer-executable instructions stored on non-transitory computer-readable media or medium.

The measurement assembly 170 and the controller 172 form a measurement system. The measurement assembly 170 is used by the controller 172 to determine the distance between the bottom 138 of the reflector 151 and the surface 111 of the silicon melt 104. Generally, a laser is focused on a quartz pin and an HR anchor value is determined using a camera viewing the reflected laser dot on the melt surface 111 and a curve fitting algorithm. Then, the laser is moved to a different quartz pin where an initial calibration is done to build a relationship between pixel location of the center of the reflected laser dot image in the melt to HR. For the remainder of the run the laser dot is constantly tracked with the camera to determine HR.

The measurement system uses a camera, laser, and one or two pins, and does not rely on contact with the melt to find HR. Both the camera and laser operate in a single cutout in the reflector covered by a window. In the example embodiment, the pins are quartz pins created from stock rod. In other embodiments, pins may be made of any high temperature refractor, such as Silicon Carbide (SiC), Silicon Nitride (SiN), Tungsten Carbide, Tantalum Carbide, or Boron Nitride. Generally, any material chosen for the pins should produce a strong, well-defined reflection on the melting surface during all interesting crystal growth phases. In the example embodiment, the stock quartz rod is 3 mm stock rod. Alternatively, stock rod of any other diameter may be used. The pins have heads formed from the rod when a long light travelling pin is needed. In this case, when the laser light needs to be seen from a pin tail but the laser light is shown on a pin head, the pins are one continuous piece, rather than a pin with a sphere welded on it, to ensure that the light from the laser is light piped to the bottom of the pin when the laser is shone on the pin head. In embodiments using a single sphere pin, the sphere may be a separate piece that is welded to the part that will attach to the reflector so that excess light does not escape the sphere. Other single sphere pin embodiments may form the sphere from the same piece of material as the rest of the pin for ease of manufacturing. The cutout in the reflector is a compound angle to allow viewing of the quartz pins from the lateral edge of the same port as the camera and laser are mounted. Unlike some known dipstick laser systems that use “open” hotzones with reflectors that do not insulate as well, the present systems are used in a “closed” hotzone where the reflector 151 fills in as much area as possible above the melt 104 with insulation. Open hotzone systems use a view around the outside of the largest crystal diameter from a port on the opposite side of the crystal as the quartz pin to see the reflection of the bottom of one of the pins illuminated by the laser in the melt. The example embodiments allow a closed hotzone, yet permit the laser dot reflection to be seen from the same port as it is shone from, while still retaining high resolution HR capability despite the steep angle of the cutout. Other embodiments may use multiple ports (e.g., with the camera and laser on different ports).

The example embodiments use a laser to shine on the head of a quartz focusing pin. Initially, the laser shines on a longer “anchor” pin. The observed height of the pin and the location of the laser dot reflection on the melt are obtained from the camera image. This is used to get the current value of HR. This creates an anchor value. Note that the quartz pin is not dipped into the melt for this method to work. The laser is then shone on the head of a shorter quartz “run” pin. A calibration of the run pin to the anchor pin is performed using the laser dot reflected image by moving through various HR values. The run pin is then used for the duration of the run including recharges and no recalibration is required unless the puller substantially changes in temperature (such as going to room temperature and then heating back up again).

Using a bright laser provides a consistent signal on the melt for both calibration and during the run. General commercially available green wavelength lasers (520 nm to 532 nm wavelength) of various power ratings are typically bright enough under all conditions. This avoids problems with some known camera system that rely on visually observing features in the hotzone that can have varying light intensity due to reflections and emission of light from the silicon melt. The light intensity variation can create shadows that can cause hotzone objects to appear to move by a pixel or two. This can create a false movement (i.e., an HR change). The consistent intensity of the laser allows for stable HR values. Because HR is used directly as an input to control of the crystal growth, a stable HR value is desired.

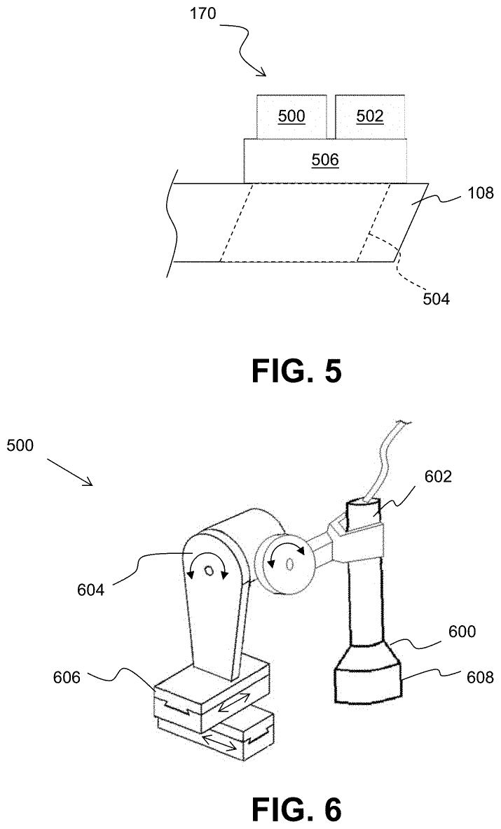

FIG. 5 is a view of a portion of the measurement assembly 170 on the outside of the crystal puller housing 108. The measurement assembly 170 includes a camera assembly 500, a laser assembly 502, and run and anchor pins (not shown in FIG. 5). The run and anchor pins are mounted inside the crystal puller housing 108, such as on the reflector 151. The measurement system includes the measurement assembly 170 and the controller 172 (not shown in FIG. 5). The camera assembly and the laser assembly are positioned over an opening 504 (sometimes referred to as a “port”) through the crystal puller housing 108 that allows the camera assembly 500 and the laser assembly 502 views of the melt 104. The opening 504 is covered by a window 506.

The camera assembly 500 is shown isolated in FIG. 6. In order to provide high resolution for HR with respect to movement of the laser dot reflection in the camera image, a long focal length lens 600 is used along with a high resolution (large pixel count) camera 602. In one example embodiment, the focal length of the lens 600 is one hundred mm, and the camera 602 has a resolution of 2560×1920 pixels. The focal length is driven by the desired range of HR to be measured. If the HR range is very large, lower focal lengths are needed so that the reflection of the laser in the melt is always within the camera image. If a narrow range of HR measurement is desired, then using a smaller focal length provides a higher resolution of mm/pixels thus providing higher accuracy. Because the design of crystal pullers is such that accurately locating ports is not always cheap or simple, the location of the port that the camera 602 is mounted on generally cannot be known accurately during the design of these new parts. Therefore, these unknowns coupled with the long focal length lens 600 result in a camera field of view that typically cannot be predictable or repeatable from machine to machine. Thus, the camera 602 is mounted on a geared tripod head 604 to allow precise movement of the camera image to encompass both the laser pin heads as well as the full range of HR travel of the laser dot reflections. The geared tripod head 604 is mounted on a two axis translation table 606 to allow further refinement of the position of the center of the angular rotations provided by the geared head: pan, tilt, and pitch. A thin wrapped sheet metal cylinder 608 is mounted to the end of the camera lens 600 which loosely interacts with another cylinder that rests (but is not mounted to anything) on the window 506 (FIG. 5). These two wrapped sheets provide cover over the window 506 to prevent shadows from affecting the camera image. Typically the camera 602 is close enough to the window that such a cover is not necessary; however, because the camera 602 is on a tripod mount 604, the camera 602 must be far enough away from the window in order to allow the camera 602 to be sufficiently adjusted without impacting the window 506.

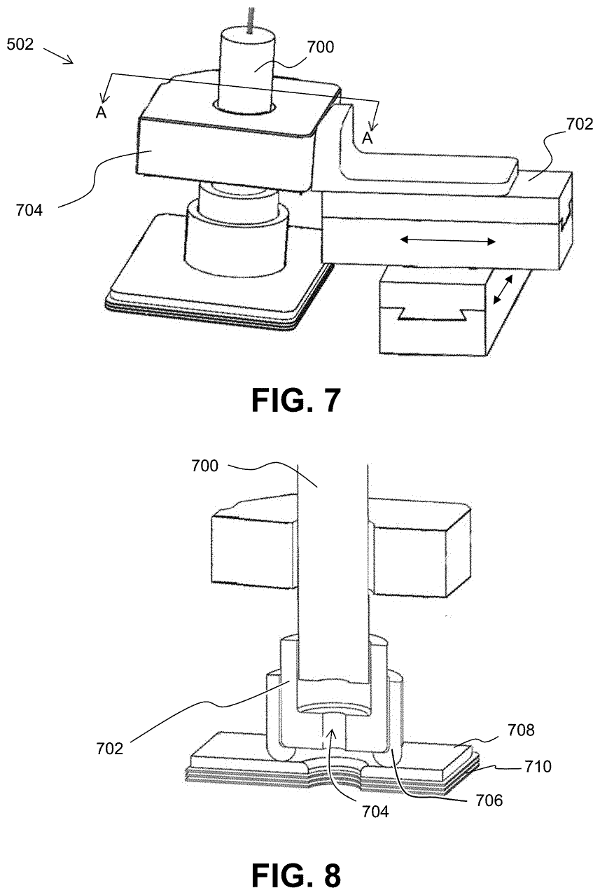

FIG. 7 is a view of the laser assembly 502 isolated. The laser 700 is mounted on two axis translation table 702 so that the laser can be precisely moved. The laser itself is mounted to a two axis gimbal 704 with micrometer adjustments to allow the laser 700 to be adjust precisely for the beam to strike the head of the pins. Only pitch and pan (yaw) are needed for the laser angular movements, because the dot does not have an orientation in the roll (tilt) direction. In one example embodiment, the laser 700 is a five milliwatt, 520 nm wavelength, diode laser with <0.3 divergence and three mm beam dimension. Because the melt is generally reddish in color, a green laser provides a more visible contrast between the dot and the melt than some other colors. Other embodiments may use any other suitable color laser.

The window 506 (FIG. 5) over the opening 904 is a coated window to reflect some of the heat coming off the melt back into the puller and therefore protect any components outside the window. The coating is a multiple atomic layer thick coating designed to reflect as much infrared energy as possible and also reflect most visible light. The coating may be, for example, a gold dielectric, a chrome oxide, or any other suitable coating. The laser 700 may not be able to produce a bright signal on the quartz pin if it had to shine through a coating. Therefore, the coating is removed in the region around where the laser strikes the window 904. However, because removal of the coating allows a large amount of heat to exit the window 904, the laser 700 needs to be protected with thermal shielding.

FIG. 8 is a cross section along the line A-A in FIG. 7 showing the thermal protection for the laser 700. A ceramic shield 702 wraps directly around the laser with a small hole 704 for the laser to shine through. A plastic body 706 wraps around the ceramic shield 702 to hold the ceramic shield 702 off of the metal surface 708 below and to create a low friction bearing surface for the laser 700 to gimbal on. The thin plates 710 below the laser 700 are radiation shields to prevent the metal body 708 from getting hot enough to damage any attached components.

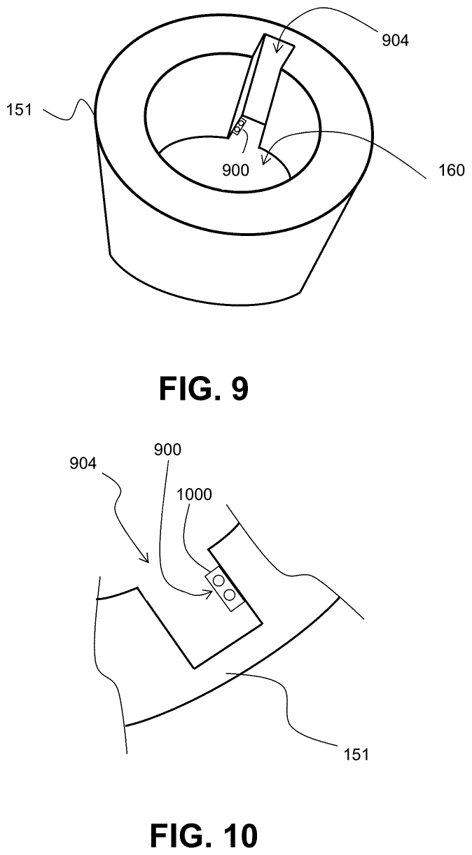

FIG. 9 is a view of the reflector 151. An opening 904 (sometimes referred to as a “notch” or a “cutout”) extends through the reflector 151, allowing the camera assembly 500 and the laser assembly 502 (not shown in FIG. 9) a view to the melt 104 through the reflector 151. In other embodiments, the opening 904 does not intersect the central passage 160. In the example embodiment, the opening 904 is angled away from the central passage 160 as the opening 904 extends away from the bottom surface 138.

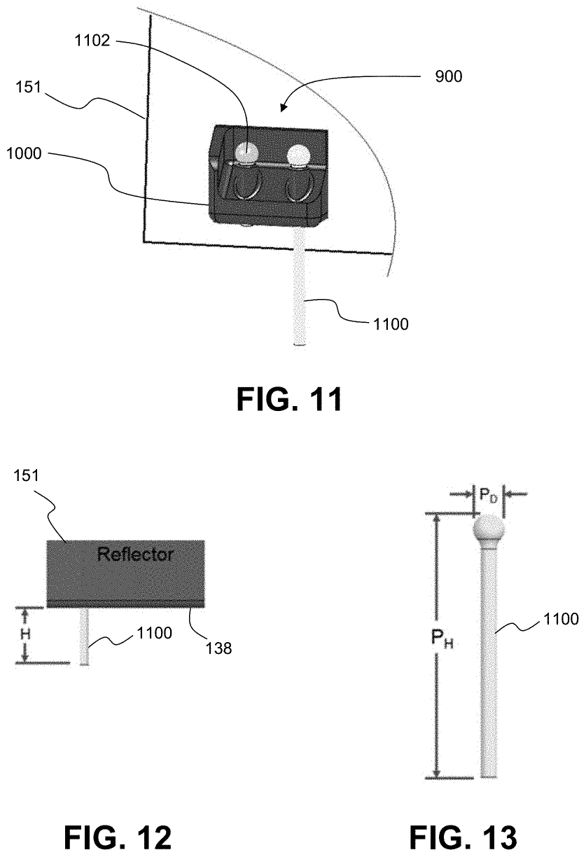

The pins 900 are barely visible near the center of the image inside the cutout 904. FIG. 10 is a view directly down the cutout 904 more clearly showing the pins 900. The pins 900 are mounted on a separate piece 1000 (also referred to as a “mount”, a “holder”, a “shelf”, or a “bracket”) extending from the reflector 151 for stress prevention, because having holes or protrusions at the edge of the reflector 151 may create stress concentration points and could lead to cracking during the run. Other embodiments have the pins 900 directly resting on holes in the reflector 151 rather than on a separate piece 1000. FIG. 11 is a close up view of the pins 900. The pins 900 include an anchor pin 1100 and run pin 1102.

In the example embodiment, the anchor pin 1100 and the run pin 1102 are attached to the reflector 151 (via the piece 1000). In other embodiments, the run pin 1102 is attached to any other surface that allows the head of the run pin to be struck by the laser and the reflection of the laser in the melt to be visible throughout the desired HR range. Using an actively cooled surface in this case is desired so the run pin 1102 would not move locations during thermal expansion of the rest of the hotzone or even from turn to turn. An example of such a surface would be the cooling jacket (water jacket). Note however this only establishes the absolute elevation of the melt and not the HR. The absolute elevation of the reflector must still be determined by some other means and then HR can be calculated from the difference between the two elevations. The absolute elevation of the reflector could be determined using the anchor method noted above to get HR and coupling that result with the absolute elevation of the melt; the absolute elevation of the reflector being the difference between the HR and absolute elevation of the melt.

To use the measurement system, an anchoring step is performed using the anchor pin 1100 to calibrate the system. After the anchoring step is performed, the run pin 1102 is used during crystal pulling to determine HR.

The anchoring step only needs to be performed one time during the startup of a run. The first step is performed before installing the reflector 151 into the puller 100. The following three items are measured as shown in FIGS. 12 and 13: the height of the anchor pin (PH), the diameter of the head of the anchor pin (PD), and the distance that the anchor pin sticks out from the bottom of the reflector (H).

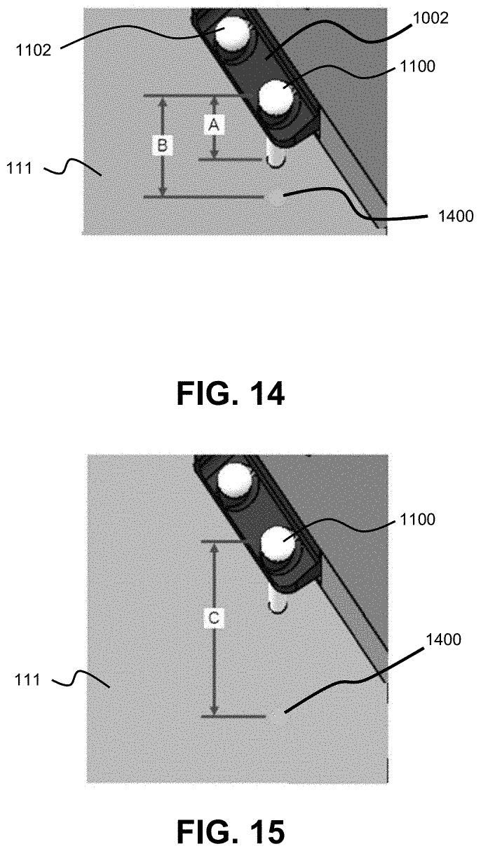

After the reflector 151 (including the reflector assembly 900) is installed in the puller 100, the laser 700 is turned on and shone on the head of the anchor pin 1100 and the camera 602 captures images. FIG. 14 is an example of a view the camera 602 may see. Because the laser is shining on the anchor pin 1100, the reflection 1400 of the bottom of the pin is visible in the melt 104 as a circle having the color of the laser light of the laser 700. The controller 172 determines the number of pixels along the distances marked as A and B. A is the number of pixels from the center of the head of the anchor pin 1100 to the bottom of the pin (the bottom being the center of the ellipse that the perspective creates). In some embodiments, the controller 172 locates the tangent edges, rather than directly finding the centers, and the previously measured pin head diameter (PD) is used to find the head center. The center of the lower edge of the pin is found using the known value of the pin diameter (either measured or not measured because it is made from stock material having a known diameter). B is the number of pixels from the center of the head of the anchor pin 1100 to the center of the reflection 1400 on the melt 104.

Next, the elevation of the melt 104 is lowered using the crucible lift 112 a known and recorded distance (known from feedback from the crucible lift) while ensuring the reflection dot 1400 does not go out of view of the camera 602. The distance that the melt is lowered is noted as ZE. This movement moves the laser dot reflection 1400 down as shown in FIG. 15. The distance C is the number of pixels from the center of the anchor pin 1100 to the center of the dot 1400 location.

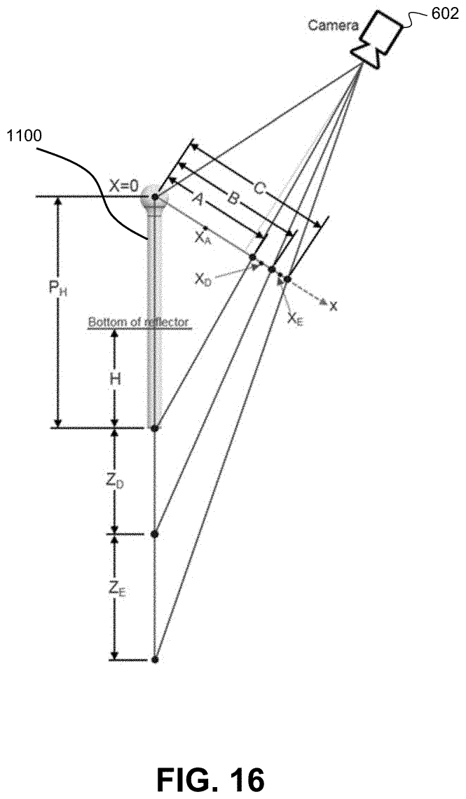

FIG. 16 diagrams the geometry and values previously discussed that are used to anchor the HR value. The following equations along with FIG. 16 are used to obtain HR:

D=B−A (1)

E=C−B (2)

Ratio A=RA=A/PH (3)

Ratio E=RE=E/ZE (4)

The X values represent distances along shown X axis in FIG. 16. Each X is at the midpoint of its subscripted segment:

XA=A/2 (5)

XD=A+D/2 (6)

XE=B+E/2 (7)

The curve fit of ratios to pixel distance is calculated as:

slope=m=(RE−RA)/(XE−XA) (8)

intercept=k=RA−m*XA (9)

RD is solved for using a linear fit:

RD=m*XD+k (10)

ZD is determined by:

ZD=D/RD (11)

Finally, HR is found from:

HR=H+ZE+ZD (12)

In some embodiments, a higher order curve fit is used rather than the linear fit using equations (8) and (9), by adding more elevation changes and recording the pixel movements. The new vertical distance changes (Z values) and the new ratios, calculated similarly to the already shown ratios, would then be added to the points used in the curve fit.

In some other embodiments, lowering the elevation of the melt by the known and recorded distance noted as ZE is omitted. In such embodiments, a simple ratio is used between A, PH, B, and PH+ZD to find ZD (and thus get HR because the melt is at elevation ZD and HR=[PH+ZD]−PH+H). However, this simple ratio ignores camera perspective and may lead to errors approaching a full millimeter or more depending on the angle of the cameras center view axis relative to the pin's main axis with smaller angle values leading to larger errors. The full anchoring described above (i.e., including ZE) allows an interpolation that accounts for the camera perspective.

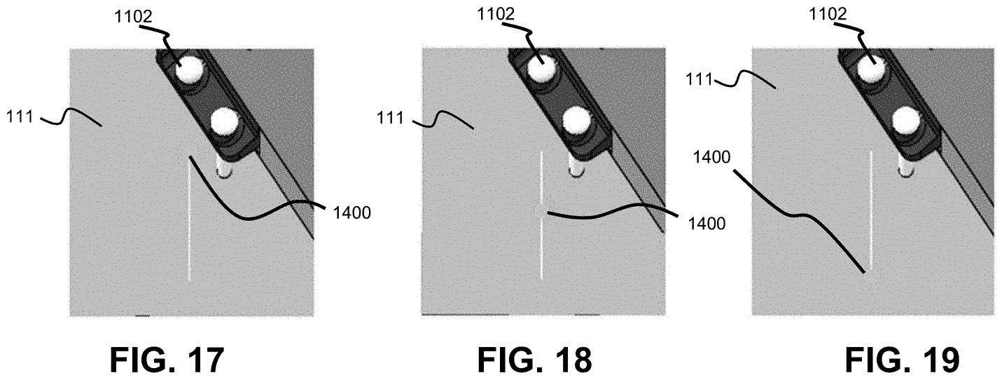

With HR now known the camera 602 can be calibrated for finding HR during the run. First, without moving the crucible lift from the end of the HR anchoring, the laser is shone on the head of the run pin 1102. The resulting location of the reflection dot 1400 represents the pixel location that correlates to the HR anchor value previously found. FIG. 17 is an example of a camera image from this step. Next, the elevation of the melt 104 is lowered via the crucible lift 112 a known and recorded distance. The pixel location of the reflection 1400 changes and is noted, as shown in the example camera image of FIG. 18. The elevation of the melt 104 is then lowered again via the crucible lift 112 a known and recorded distance. location of the reflection 1400 changes and is noted, as shown in the example camera image of FIG. 18. Using the recorded pixel locations and the known changes in HR (from the recorded changes in the elevation of the melt 104), a curve fit is created for HR as a function of pixel location. A sine term is involved between the relationship of HR and pixel location. Therefore, a minimum of a 2nd order curve fit is used to avoid errors in the one millimeter range that result from a linear fit.

After performing the above steps, the HR can now be determined during any time of the run by locating the center of the laser dot reflection 1400 on the camera image and using the relationship created above to find HR.

In some other embodiments, instead of doing hot calibrations, the laser reflections 1400 could be observed using a first surface mirror in a cold puller 100. This would allow corresponding HR values to be determined prior to the run. However, calculations would have to be done to estimate thermal expansion of the reflector 151 to reconcile offsets in the pixel locations of the laser dot 1400 on the camera images. This cold calibration method may introduce unnecessary error, because the exact temperatures and material properties may not be precisely known.

Some embodiments include a reflector 151 that moves during the run. This results in additional component of movement of the laser dot on the camera image requiring additional points that must be calibrated.

The example embodiment uses separate pins for the run pin 1102 and the anchor pin 1100 because the full height of the anchor pin 1100 should be visible during anchoring to determine HR without dipping the anchor pin 1100 in the melt 104. However, seeing the full height of the pin is not desired during the run. Using separate pins allows the camera to more easily determine the center of the laser dot reflection in the melt during the run when it is nearly a circle. For this reason, the run pin 1102 is much shorter than the anchor pin 1100 and is nearly flush such that primarily the reflection 1400 of the bottom of the run pin 1102 is visible in the melt 1104. A shorter pin also provides protection against loss of measurement capability in the event the pin is broken, which would be more likely if the pin was longer. Even if the anchor pin 1100 breaks any time after the calibration, it does not affect the ability to determine HR since that is done with the run pin 1102. Other embodiments include a single pin that is used as both an anchor pin and the run pin.

The lifetime of commonly available lasers can vary from a few months to just over a year when run at 100% duty cycle (on all the time). Because HR does not need to be known more once than every few seconds, the measurement system only turns on the laser 700 as needed every few second, thus extending the life of the laser 700. With a one second on time and nine second off time a one year 100% duty cycle laser can be made to last ten years. The laser 700 can also be turned off when the puller 100 is not hot resulting in even longer lifetimes. Different embodiments may keep the laser on all the time, simply requiring replacement more often.

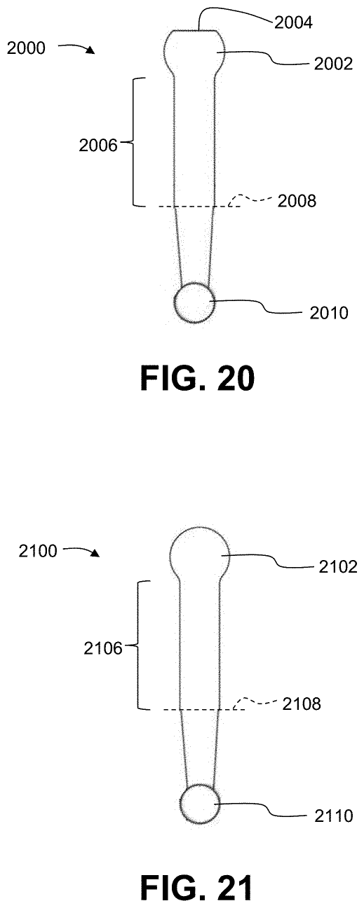

FIGS. 20 and 21 are side views of two alternative pins 2000 and 2100 that may be used as the run pin 1102, the anchor pin 1100, or a combination run/anchor pin in a single pin setup. The pin 2000 has a spherical head 2002 with a flat top 2004. In an example embodiment, the head 2002 has a diameter of about 4.5 mm. A main body portion 2006 of the pin 2000 is generally cylindrical. At about the level 2008 where the pin 2000 will begin to extend past the bottom of reflector 151 when installed, the pin 2000 tapers to a smaller, spherical end 2010. In an example embodiment, the spherical end 2010 has a diameter of about 3.0 mm. In some embodiments, the tapered portion of the pin 2000, a top portion of the spherical end 2010, and a lower portion of the main body portion 2006 are clear, while the rest of the pin 2000 is opaque. The pin 2100 in FIG. 21 is substantially the same as the pin 200, but has a spherical head 2102. In an example embodiment, the head 2102 has a diameter of about 4.5 mm. A main body portion 2106 of the pin 2100 is generally cylindrical. At about the level 2108 where the pin 2100 will begin to extend past the bottom of reflector 151 when installed, the pin 2100 tapers to a smaller, spherical end 2110. In an example embodiment, the spherical end 2110 has a diameter of about 3.0 mm. In some embodiments, the tapered portion of the pin 2100, a top portion of the spherical end 2110, and a lower portion of the main body portion 2106 are clear, while the rest of the pin 2100 is opaque.

Another embodiment uses a single pin with only one sphere (one head). A single sphere pin is used with the laser shining on the sphere. The top of the sphere is visible to the laser and camera and the reflection of the bottom of the sphere in the melt is visible by the camera. The single sphere may be at the end of a longer pin that is used in supporting the pin or it may be a small sphere with minimal other parts. The laser shines on the top surface of the pin. The reflection in the melt described in the other embodiments that is used for calibration and HR determination is the bottom of the sphere. There is no substantial change in the methods described in other embodiments to calibrate or determine HR. The last 4 figures show examples of single sphere pins.

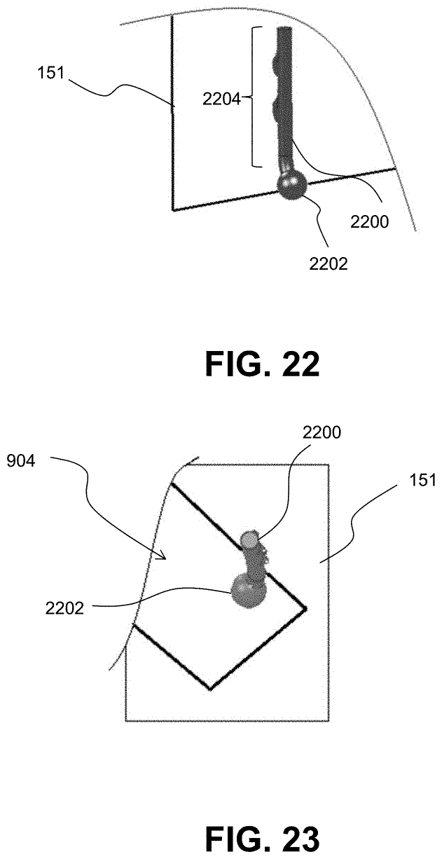

FIGS. 22 and 23 are views of such a single pin embodiment in which a pin 2200 includes a spherical head 2202. The remaining portion 2204 of the pin 2200 is for mounting the pin 2200 to the reflector 151, and is not used for directing laser light. FIG. 22 is a view from within the opening 904 in the reflector 151 approximately level with the pin 2200, with the portion 2204 of the pin 2200 attached to a wall of the reflector 151 in the opening 904. FIG. 23 is a view of the pin 2200 down the opening 904 (e.g., as seen by the camera 602). laser light is shined at the top (e.g., the portion visible in FIG. 23)

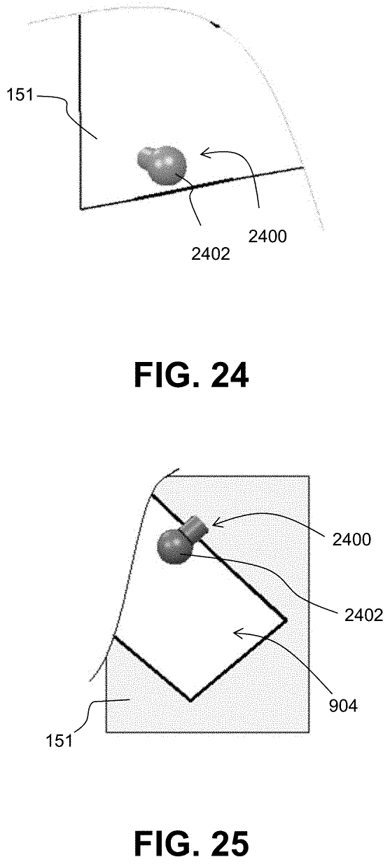

FIGS. 24 and 25 are views of another such single pin embodiment in which the useful portion of the pin 2400 is the spherical head 2402 only. FIG. 24 is a view from within the opening 904 in the reflector 151 approximately level with the pin 2400 extending from a wall of the reflector 151 in the opening 904. FIG. 25 is a view of the pin 2400 down the opening 904 (e.g., as seen by the camera 602). In this embodiment, the upper portion of the spherical head 2402 (e.g., the portion seen in FIG. 25) receives strong monochromatic green light from the laser as described in the other embodiments and the lower portion of the quartz sphere (e.g., the portion opposite the portion seen in FIG. 25) is frosted or semi-transparent to scatter the light to generate a clear spherical reflection on the melt surface (not shown in FIG. 25). The semi-transparent portion is created using a surface coating or etching of the surface of the pin. Any suitable coating or other method of producing a translucent, light scattering portion of the pin may be used. In other embodiments, different portions or additional portions of the pin may be similarly semi-transparent and light scattering.

In the embodiments of FIGS. 22-25, the calibration process is similar to the other embodiments described above, but using only a single sphere head and a single reflection. Three separate image locations of the spherical reflection centroid are captured as the melt position is changed—“high”, “mid”, and “low” position. At each location the X and Y image pixel coordinates are captured and stored. Also, the position of the crucible lift system which moves the melt up and down is captured and stored. In addition, the location of the spherical is captured and likewise the X and Y coordinates of the sphere center are captured and stored for each position.

Utilizing the coordinates and crucible positions stored in the first step, parameters are calculated for a second order fit that will produce a crucible position when given the centroid coordinates of the spherical reflection. With these parameters the crucible position can be calculated within the full range of travel by using the image coordinates.

Next, using the coordinates of the centroid of the spherical head captured in the second step and the addition of the measurement of the spherical head center to bottom of the reflector, the calibration is modified so that the fitting parameters can now be used to calculate the distance between the melt top surface and the bottom of the reflector.

As shown in FIGS. 17-19, with the camera 602 in a fixed position, the reflection 1400 should travel in a straight line as the melt level changes, and the run pin 1102 (or a combined run and anchor pin) should remain in the same location in each image captured by the camera. If the run pin 1102 moves in the plane of the image or tilts with respect to the camera 602 during operation, the reflection 1400 may not move in the anticipated straight line and the calculations discussed above may need to be adjusted. Such movement may be caused, for example, by vibration experienced by the ingot puller apparatus 100, by expansion or contraction of materials of the pin, the mount 1000, or other components within the growth chamber 152 because of the thermal conditions in the growth chamber, or the like.

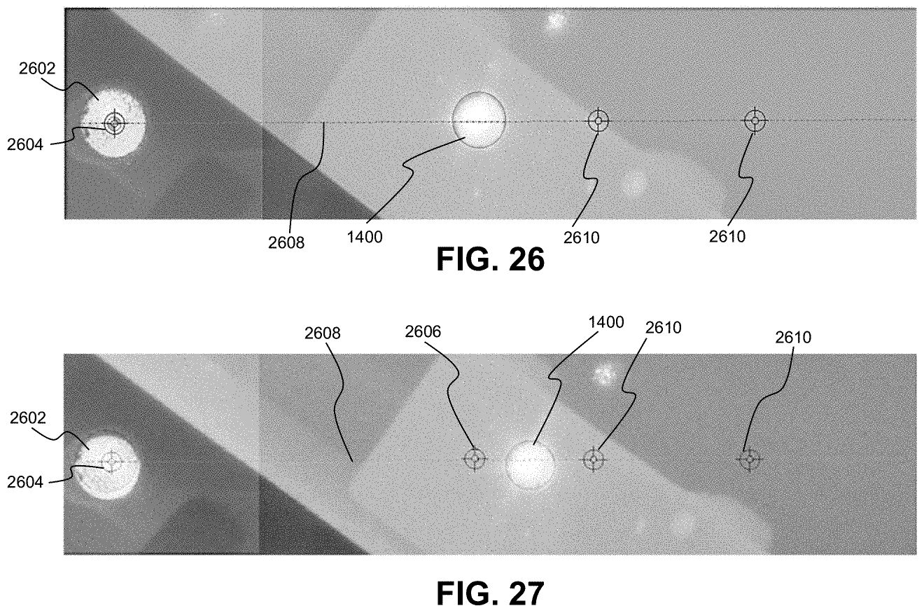

FIGS. 26 and 27 are example images captured by the camera at the during a run (after the system has been calibrated as discussed above). In FIG. 26, the illuminated pin 2602 is aligned centered on a first target 2604. The reflection 1400 is aligned centered on a second target 2606 (visible in FIG. 27). The line 2608 is a tracking line along which it is anticipated that the reflection 1400 will move as the melt level changes during the run. The additional targets 2610 are additional registration points defined during calibration.

FIG. 27 shows the illuminated pin 2602 and the reflection 1400 at a later time than in FIG. 26. That is, the ingot puller apparatus 100 has been running for some time after the image in FIG. 26 was captured. As can be seen, the pin 2602 has shifted from its original position. The reflection 1400 has also shifted from the tracking line 2608.

To at least partially correct for the shifts, an offset vector from the center of the first target 2604 to the center of the illuminated pin (shown in FIG. 27) is determined, and the same offset vector is applied to the reflection 1400. In some embodiments, the offset vector is determined by determining distance in pixels in the X direction and the Y direction of the image from the center of the first target 2604 to the center of the pin 2602. This correction aligns the reflection of the pin head to the location of the pin head by adding the same offset to the reflection.

Any logic flows depicted in the figures do not require the particular order shown, or sequential order, to achieve desirable results. In addition, other steps may be provided, or steps may be eliminated, from the described flows, and other components may be added to, or removed from, the described systems. Accordingly, other embodiments are within the scope of the following claims.

It will be appreciated that the above embodiments that have been described in particular detail are merely example or possible embodiments, and that there are many other combinations, additions, or alternatives that may be included.

Also, the particular naming of the components, capitalization of terms, the attributes, data structures, or any other programming or structural aspect is not mandatory or significant, and the mechanisms that implement the disclosure or its features may have different names, formats, or protocols. Further, the system may be implemented via a combination of hardware and software, as described, or entirely in hardware elements. Also, the particular division of functionality between the various system components described herein is merely one example, and not mandatory; functions performed by a single system component may instead be performed by multiple components, and functions performed by multiple components may instead performed by a single component.

Approximating language, as used herein throughout the specification and claims, may be applied to modify any quantitative representation that could permissibly vary without resulting in a change in the basic function to which it is related. Accordingly, a value modified by a term or terms, such as “about” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

Various changes, modifications, and alterations in the teachings of the present disclosure may be contemplated by those skilled in the art without departing from the intended spirit and scope thereof. It is intended that the present disclosure encompass such changes and modifications.

This written description uses examples to describe the disclosure, including the best mode, and also to enable any person skilled in the art to practice the disclosure, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A real-time measurement system in a crystal puller for determining a distance between a silicon melt in a crucible and a reflector while a crystal is being pulled from the silicon melt, the system comprising:
a reflector defining a central passage through which the crystal is pulled and an opening;
a measurement assembly comprising:
a run pin having a head that is visible through the opening;
a camera to capture images through the opening in the reflector, each captured image including a surface of the silicon melt in the crystal puller; and
a laser to selectively transmit coherent light through the opening to the head of the run pin to produce a reflection of the run pin on the surface of the silicon melt; and
a controller connected to the camera and the laser, the controller programmed to:
control the laser to direct coherent light from the laser to the run pin,
control the camera capture images through the opening in the reflector while the coherent light is directed at the run pin, the captured images including at least a part of the surface of the silicon melt on which the reflection of the run pin is visible, and
determine a distance between the surface of the silicon melt and a bottom surface of the reflector based on a location of the reflection of the run pin in the captured images.

2. The measurement system of claim 1, wherein the run pin is mounted in the reflector.

3. The measurement system of claim 1, wherein the run pin includes an end opposite the head of the pin, the reflection of the run pin is a reflection of the end of the run pin, and the end of the run pin is not visible to the camera through the opening.

4. The measurement system of claim 1, wherein the run pin comprises a quartz run pin.

5. The measurement system of claim 1, wherein the end of the run pin is sized and positioned to prevent the run pin from touching the surface of the silicon melt when a crystal is being pulled from the silicon melt.

6. The measurement system of claim 1, further comprising an anchor pin mounted to the reflector, the anchor pin including a head and an end opposite the head, the anchor pin being sized to extend past a bottom surface of the reflector.

7. The measurement system of claim 6, wherein the controller is programmed to calibrate the system using the anchor pin without touching the anchor pin to the silicon melt, and the calibration occurs before determining the distance between the surface of the silicon melt and the bottom surface of the reflector while a crystal is being pulled from the silicon melt.

8. The measurement system of claim 7, wherein the controller is programmed to calibrate the system by:
controlling the laser to direct coherent light from the laser to the head of the anchor pin,
control the camera capture images through the opening in the reflector assembly while the coherent light is directed at the anchor pin, the captured images including at least a part of the anchor pin and at least a part of the surface of the silicon melt on which a reflection of the end of the anchor pin is visible, and
determine a distance between the surface of the silicon melt and a bottom surface of the reflector based at least in part on a location of the reflection of the end of the anchor pin in the captured images, known dimensions of the anchor pin, and an amount by which the anchor pin extends past the bottom surface of the reflector.

9. The measurement system of claim 8, wherein the controller is programmed to:
control the camera capture images while calibrating the system by:
controlling the camera to capture a first image through the opening in the reflector assembly while the coherent light is directed at the head of the anchor pin and the surface of the melt is at a first distance from the bottom of the reflector;
controlling the camera capture a second image through the opening in the reflector assembly while the coherent light is directed at the head of the anchor pin when the surface of the melt is at a second distance from the bottom of the reflector; and
determine the distance between the surface of the silicon melt and the bottom surface of the reflector while calibrating the system based at least in part on the first and second images.

10. The measurement system of claim 9, wherein the controller is programmed to control a crucible lift to move the crucible to change the distance between the surface of the silicon melt and the bottom surface of the reflector by known amounts.

11. The measurement system of claim 9, wherein the controller is further programmed to calibrate the system by:
controlling the laser to direct coherent light from the laser to the head of the run pin when the surface of the melt is at the second distance from the bottom of the reflector;
controlling the camera to capture run calibration images through the opening in the reflector assembly while the coherent light is directed at the run pin, the run calibration images including at least a part of the surface of the silicon melt on which the reflection of the end of the run pin is visible;
correlate the location of the reflection of the end of the run pin in the run calibration images to a reflection of the end of the anchor pin in the second image.

12. A system for producing a silicon ingot, the system including:
a crucible for holding a silicon melt; and
the measurement system of claim 1.

13. A wafer generated from a silicon ingot produced using the system of claim 12.

14. A method of determining a distance between a silicon melt in a crucible and a reflector in a crystal puller while a crystal is being pulled from the silicon melt using a measurement system including a camera, a laser, a run pin, and a controller, the method comprising:
directing coherent light from the laser to the run pin mounted on the reflector and visible through an opening in the reflector;
capturing images through the opening in the reflector using the camera while the coherent light is directed at the run pin, the captured images including at least a part of a surface of the silicon melt on which the reflection of the run pin is visible; and
determining, by the controller, a distance between the surface of the silicon melt and a bottom surface of the reflector based on a location of the reflection of the run pin in the captured images.

15. The method of claim 14, wherein the measurement system includes an anchor pin mounted to the reflector and having a head and an end opposite the head, the anchor pin being sized to extend past a bottom surface of the reflector, and wherein the method further comprises: calibrating the measurement system using the anchor pin without touching the anchor pin to the silicon melt before determining the distance between the surface of the silicon melt and the bottom surface of the reflector while a crystal is being pulled from the silicon melt.

16. The method of claim 15, wherein calibrating the measurement system further comprises:
directing coherent light from the laser to the head of the anchor pin,
capturing images through the opening in the reflector assembly while the coherent light is directed at the anchor pin using the camera, the captured images including at least a part of the anchor pin and at least a part of the surface of the silicon melt on which a reflection of the end of the anchor pin is visible; and
determining a distance between the surface of the silicon melt and a bottom surface of the reflector based at least in part on a location of the reflection of the end of the anchor pin in the captured images, known dimensions of the anchor pin, and an amount by which the anchor pin extends past the bottom surface of the reflector.

17. The method of claim 16, wherein capturing images through the opening in the reflector assembly while the coherent light is directed at the anchor pin using the camera comprises:
capturing a first image through the opening in the reflector assembly while the coherent light is directed at the head of the anchor pin and the surface of the melt is at a first distance from the bottom of the reflector; and
capturing a second image through the opening in the reflector assembly while the coherent light is directed at the head of the anchor pin when the surface of the melt is at a second distance from the bottom of the reflector, and wherein determining the distance between the surface of the silicon melt and the bottom surface of the reflector while calibrating the measurement system is based at least in part on the first and second images.

18. The method of claim 17, further comprising controlling a crucible lift to move the crucible to change the distance between the surface of the silicon melt and the bottom surface of the reflector by known amounts.

19. A system for producing a silicon ingot, the system including:
a crucible for holding a silicon melt; and
the measurement system configured to perform the method of claim 14.

20. A wafer generated from a silicon ingot produced using the system of claim 19.
